(19) United States
(12) Patent Application Publication
(10) Pub. No.: US 2018/0292463 A1
(43) Pub. Date: Oct. 11, 2018

(54) METHOD AND SYSTEM FOR BATTERY STATE OF CHARGE CALCULATION

(71) Applicant: Lear Corporation, Southfield, MI (US)

(72) Inventors: Jose Antonio CANALS ESTEVE, Valls (ES); Antoni FERRE FABREGAS, Valls (ES); David GAMEZ ALARI, Valls (ES)

(21) Appl. No.: 15/875,277

(22) Filed: Jan. 19, 2018

Related U.S. Application Data
(60) Provisional application No. 62/483,699, filed on Apr. 10, 2017.

(51) Int. Cl. G01R 31/36

(52) U.S. Cl. CPC G01R 31/3651; G01R 31/362

(57) ABSTRACT

Method and system to improve the calculation of the State of Charge (SOC) of a battery with a model based on an adaptive parabolic function, including a feature to dynamically update the key parameters of the model, to compensate the behavior deviations of the battery from the ideal new battery model as it ages. The battery model has a parabolic region and a linear region.

### CROSS-REFERENCE TO RELATED APPLICATIONS

This application claims the benefit of U.S. provisional application Ser. No. 62/483,699 filed Apr. 10, 2017, the disclosure of which is hereby incorporated in its entirety by reference herein.

### TECHNICAL FIELD

The present disclosure relates to a method and system for estimating or calculating a battery state of charge (SOC), and more particularly to a method and system of calculating a battery SOC using an adaptive parabolic open circuit voltage (OCV) versus SOC model.

### BACKGROUND

The amount of fuel remaining in a vehicle fuel tank can be directly measured with different sensor technologies. However, the state of charge (SOC) of a battery cannot be directly measured; it must be estimated. Different strategies have been implemented to get a correct value of the SOC signal. When the electric system of a vehicle is active (i.e., charging or discharging), the variation of the SOC signal may be estimated using a Coulomb counting strategy. The Coulomb counting method integrates the output (or input) current to obtain the amount of electrical charge that has been extracted (or loaded) from the battery.

### SUMMARY

One or more embodiments of the present disclosure is related to a method for calculating the state of charge (SOC) of a battery. The method may comprise determining initial model parameters for an open circuit voltage (OCV) versus depth of discharge (DOD) battery model; obtaining model constants from the model parameters; measuring voltage of the battery; and calculating the SOC based on the voltage and the battery model.

One or more additional embodiments of the present disclosure is related to a battery monitoring system that includes a battery, a battery sensor connected to the battery, and an energy management system coupled to the battery sensor. The energy management system may be configured to calculate the state of charge (SOC) of the battery using a dynamic open circuit voltage (OCV) versus depth of discharge (DOD) battery model having a parabolic region and a linear region.

One or more additional embodiments of the present disclosure is related to an energy management system for a vehicle battery comprising an estimation unit and a controller. The estimation unit may be configured to: determine initial model parameters for an open circuit voltage (OCV) versus depth of discharge (DOD) battery model; obtain model constants from the model parameters; receive a voltage measured from poles of the vehicle battery; and calculate a state of charge (SOC) of the vehicle battery based on the voltage and the battery model. The controller may be configured to send control signals to vehicle loads or an alternator based on the SOC of the battery.

### BRIEF DESCRIPTION OF THE DRAWINGS

FIG. 1 is a simplified block diagram of battery monitoring system for a vehicle, in accordance with an embodiment of the present disclosure;

FIG. 2 is a typical OCV vs. SOC model for estimating battery SOC;

FIG. 3 is a dynamic, piecewise-defined OCV vs. DOD (Depth of Discharge) model having two main regions, one parabolic and one linear, for estimating battery SOC, in accordance with one or more embodiments of the present disclosure;

FIG. 4a shows an update function for a slope (S) model parameter, in accordance with an embodiment of the present disclosure;

FIG. 4b shows an update function for a fully-charged open circuit voltage (OCV_FC) model parameter, in accordance with an embodiment of the present disclosure; and

FIG. 5 is a simplified, flow diagram depicting a method 500 for calculating the SOC of the battery, in accordance with one or more embodiments of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

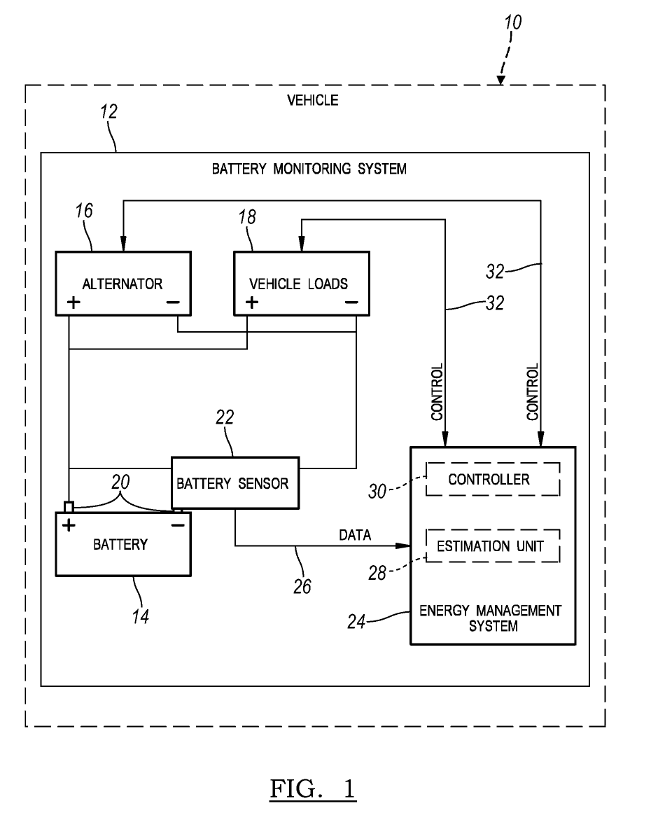

FIG. 1 illustrates a vehicle 10 having a battery monitoring system (BMS) 12 comprising one or more batteries 14. The BMS 12 may include at least one battery 14, such as a typical 12-volt battery. The BMS 12 may monitor battery conditions, such as the SOC and State of Health (SOH) of the battery.

The battery 14 may be connected to an alternator or generator 16, as well as to vehicle loads 18, such as an electric motor, inverter, additional batteries, accessories, or the like. The battery 14 may provide electrical energy to the vehicle loads 18 and receive electrical energy from the alternator 16. The vehicle loads 18 may also receive electrical energy directly from the alternator 16. The battery 14 may include both positive and negative poles 20. A battery sensor 22 may be connected directly to one of the battery poles 20. The battery sensor 22 may measure battery characteristics such as battery voltage, battery current, and the like.

The BMS 12 may further include an electrical energy management system 24 coupled to the battery sensor 22. The energy management system 24 may receive data signals 26 from the battery sensor 22 indicative of battery conditions and characteristics. The energy management system 24 may include a battery estimation unit 28 and a controller 30. The estimation unit 28 may estimate the SOC of the battery 14 based on a dynamic model described in detail below. The controller 30 may be a dedicated battery controller, such as a battery control module (BCM). Alternatively, the controller 30 may be a general vehicle controller, such as a vehicle system controller/powertrain control module (VSC/PCM). The controller 30 may be coupled to the battery 14, the battery sensor 22, and the estimation unit 28, and may send control signals 32 based on the SOC of the battery. For example, the controller 30 may send control signals to the vehicle loads 18 or the alternator 16, as shown in FIG. 1.

The electrical energy management system 24 may require an accurate measurement of the SOC of the battery 14. The present disclosure relates to a system, method, and model for obtaining an accurate measurement of the battery SOC. The battery SOC calculation method may be applied to lead-acid batteries or the like.

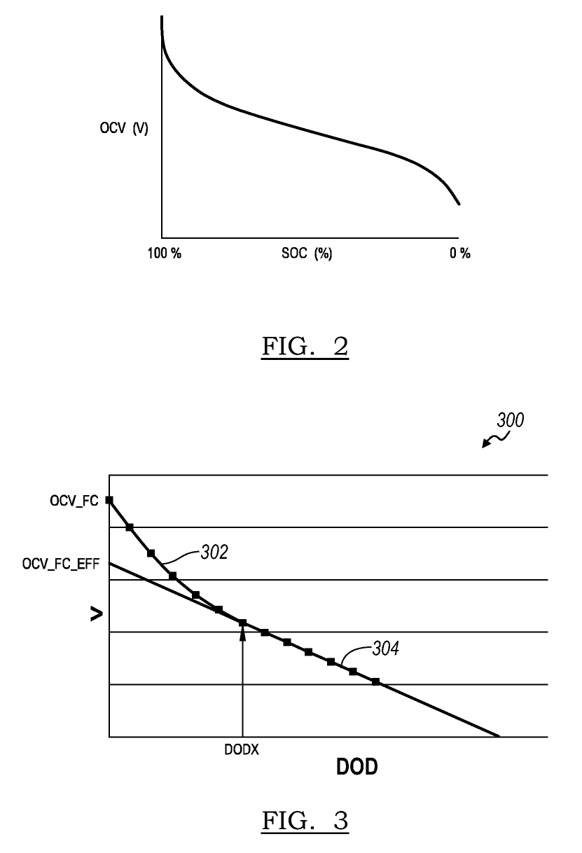

As previously explained, the variation of the SOC signal may be estimated using a Coulomb counting strategy, which integrates the output (or input) current to obtain the amount of electrical charge that has been extracted (or loaded) from the battery. Coulomb counting has the inherent problem of an offset accumulation present in all integration-based algorithms. The offset integration can be minimized with an accurate current measurement, but not disregarded. Correction methods have been used to compensate for the error introduced by current integration. The most commonly employed correction method uses a relationship between the SOC and the open circuit voltage (OCV) when the battery is stabilized after a defined rest period. This relationship is normally nonlinear, as can be observed in FIG. 2. Vehicle manufactures often incorporate in their devices a set of OCV-SOC mappings, based on Look Up Tables (LUT) for different battery models. The real behavior of a particular battery is unlikely to exactly match the model. In addition, those models are fixed and do not adapt to the variation of the behavior of the battery. This effect becomes stronger as the battery ages. The present disclosure describes an adaptive non-linear OCV-SOC model.

Although the relationship between SOC and OCV is almost linear in a wide range of SOC, the battery is likely to be working in the upper nonlinear segment. With reference to FIG. 3, the present disclosure depicts a new mathematical model 300 for the OCV vs. DOD (Depth of Discharge) based on a piecewise-defined function. It also describes the process to dynamically adjust key parameters of the model to match the model with the actual behavior of the battery 14. Dynamically updating the key parameters of the model compensates for the behavior deviations of the battery as it ages.

For practical reasons, the model may be defined in terms of Depth of Discharge (DOD) instead of SOC. Equation 1 shows the relationship between DOD and SOC:

DOD (%)=100−SOC (%) Eq. 1:

As shown in FIG. 3, the proposed model 300 may be a mixed model including two main regions: a parabolic region 302 in the upper side and a linear region 304 in the lower side. Four model parameters may be needed to construct the model and may be obtained through a battery characterization process:
OCV_FC: The voltage in the poles 20 of the battery 14 when the battery is fully charged. A settle time period may be elapsed after charging the battery 14 in order to get a good stable value of OCV_FC.
S: Slope of the OCV vs DOD function in the linear region. A slow discharge with intermediate settle periods must be performed to obtain this parameter.
OCV_FC_EFF: Intersection point of the OCV vs DOD function in the linear region with the DOD=0 axis.
DODX: This parameter is defined as the union point between the parabolic and the linear parts of the model. Experimental results show that a recommended value of DODX should remain between 15% and 30%. However, the value of DODX may be adjusted up or down based on the specific battery application or configuration.

The complete model expression can be expressed according to Equation 2:

$$V ( DOD ) = \{ \begin{matrix}{C}_{2} {DOD}^{2} + {C}_{1} DOD + {C}_{0} & DOD < DODX \\ {C}_{4} DOD + {C}_{3} & DOD \geq DODX\end{matrix} \qquad Eq . 2$$

The model constants in the linear region 304 (C₃ and C₄) can be directly obtained from the configuration (model) parameters (Eq. 3, 4):

C₄=S Eq. 3:

C₃=OCV_FC_EFF Eq. 4:

In order to obtain the constants for the parabolic region 302 (C₀, C₁ and C₂), three assumptions may be made:

The model voltage may equal OCV_FC when DOD=0 (Equation 5)

The function may be continuous in DOD=DODX (Equation 6)

The derivative of the function may be continuous in DOD=DODX (Equation 7)

$$\begin{matrix}V ( 0 ) = OCV\_FC & Eq . 5 \\ V ( {DODX}^{+} ) = V ( {DODX}^{-} ) & Eq . 6 \\ \frac{dV}{dDOD} ( {DODX}^{+} ) = \frac{dV}{dDOD} ( {DODX}^{-} ) & Eq . 7\end{matrix}$$

The values of the constants in the parabolic region 302 (C₀, C₁ and C₂) may then calculated per Equations 8, 9 and 10:

$$\begin{matrix}{C}_{2} = \frac{OCV\_FC - OCV\_FC \_EFF}{{DODX}^{2}} & Eq . 8 \\ {C}_{1} = S + 2 \frac{OCV\_FC \_EFF - OCF\_FC}{DODX} & Eq . 9 \\ {C}_{0} = OCF\_FC & Eq . 10\end{matrix}$$

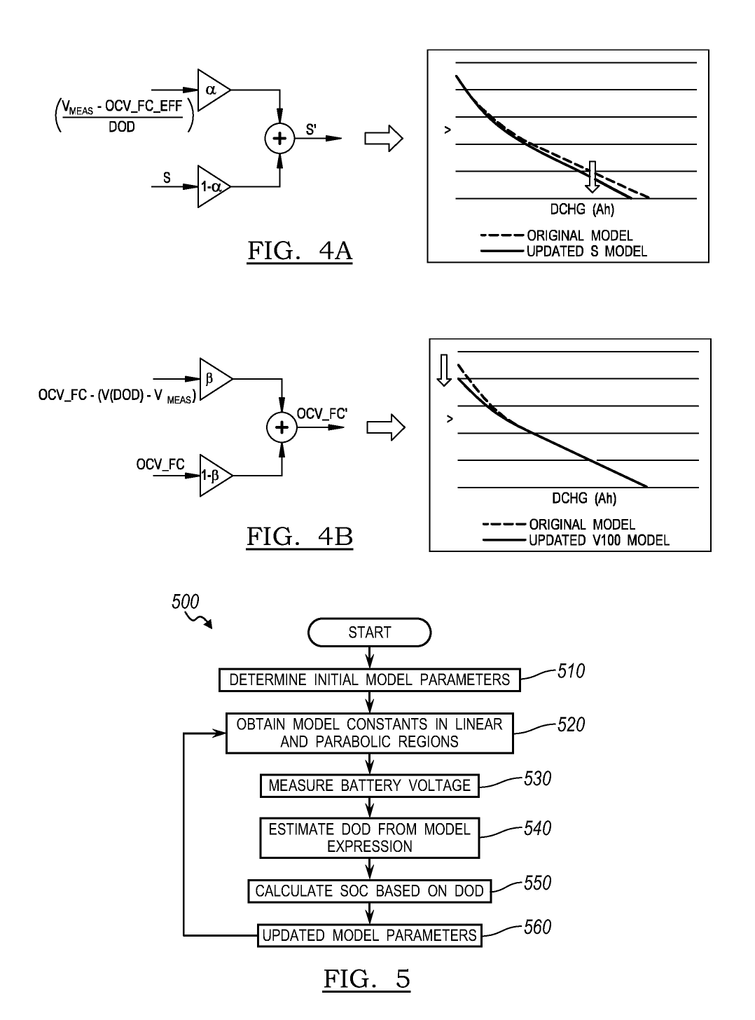

The proposed algorithm can readjust some model parameters when (e.g., due to aging) the measured OCV-SOC relationship deviates from the internal model. For instance, a common effect when a battery ages is a variation of the slope (S) between OCV and DOD. This effect may be continuously measured and incorporated to the above model by updating the values of the model parameters. To update the Slope parameter, as shown in FIG. 4a, some conditions may first be met in the system:
The voltage in the poles of the battery must be stable for a defined period of time
The current value of DOD must be above DODX
For consistency reasons, the current value of DOD should remain below a security maximum value. Experimental results show a recommended value for this threshold may be around 70%. However, this threshold value may be adjusted up or down based on the specific battery application or configuration.

The real voltage of the battery, Vₘₑₐₛ, may be measured between the battery poles. If the above-described three conditions are met, a new value of the Slope (S′) may be calculated according to Equation 11:

$${S}^{′} = α ( \frac{{V}_{meas} - OCV\_FC \_EFF}{DOD} ) + ( 1 - α ) S \qquad Eq . 11$$

As shown in FIG. 4a and Equation 11, the learning rate of the Slope may be adjusted with the filter constant α. The bigger the value of this constant, the faster the learning response. The value of this constant may also depend on the periodicity of the learning procedure.

When the battery 14 is fully charged, the value of the parameter OCV_FC may also be updated, as shown in FIG. 4b. The conditions that the system should meet in order to update this parameter are:

The voltage in the poles 20 of the battery 14 are stable for a defined period of time

The battery is fully charged (DOD<3%)

If these conditions are met, the new value of the open circuit voltage when fully charged (OCV_FC′) may be calculated according to Equation 12:

OCV_FC′=β(OCV_FC−(V(DOD)−Vₘₑₐₛ))+(1−β)OCV_FC Eq. 12:

The filter constant β may be affected by the same restrictions as α.

Each time a configuration parameter is updated (S or OCV_FC), the model constants should be recalculated according to Equations 3, 4, 8, 9 and 10. The battery SOC value obtained from direct current integration may then be recalibrated using the above-described model. Further, the state of health (SOH) of the battery may be inferred from the values of the model parameters.

FIG. 5 is a simplified, flow diagram depicting a method 500 for calculating the SOC of the battery 14, in accordance with one or more embodiments of the present disclosure. As disclosed above, the mathematical model 300 for OCV vs. DOD used to calculate the SOC of the battery is based on a piecewise-defined function having two regions—a parabolic region 302 in the upper side and a linear region 304 in the lower side. Further, the key parameters of the model may be dynamically updated to match the behavior of the battery 14 as it ages. The initial parameters for the model may be determined at step 510. The model parameters may include OCV_FC, S, OCV_FC_EFF, and DODX as previously described.

At step 520, the model constants for the model expression in Equation 2 may be obtained from the model parameters using, for example, Equations 3, 4, 8, 9 and 10 under the proper conditions and assumptions described above. The battery sensor 22 may then measure the battery voltage, as provided at step 530. At step 540, the battery estimation unit 28 may estimate or otherwise calculate the Depth of Discharge (DOD) of the battery from the model based on the measured voltage. Once the DOD is obtained, the SOC of the battery may be calculated using Equation 1, as provided at step 550. The battery SOC may be used to determine the vehicle range, powertrain operating modes, among other things.

The method may then proceed to step 560. At step 560, the model parameters may be updated. For example, the Slope parameter, S, may be updated according to Equation 11 to obtain S′. Similarly, the OCV_FC parameter may be updated according to Equation 12 to obtain OCV_FC′. The updated model parameters S′ and OCV_FC′ become S and OCV_FC, respectively, at the next iteration. That is, once the model parameters are updated, the method may return to step 520 to calculate new (updated) model constants based on the updated model parameters.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for calculating a state of charge (SOC) of a battery comprising:
determining initial model parameters for an open circuit voltage (OCV) versus depth of discharge (DOD) battery model having a parabolic region and a linear region;
obtaining model constants for the battery model from the initial model parameters;
measuring voltage of the battery; and
calculating the SOC based on the voltage and the model constants of the battery model.

2. The method of claim 1, wherein calculating the SOC based on the voltage and the battery model comprises:
estimating the DOD of the battery from the battery model based on the measured voltage of the battery; and
calculating the SOC based on DOD.

3. The method of claim 1, further comprising:
updating the initial model parameters to obtain updated model parameters for the battery model; and
obtaining updated model constants from the updated model parameters.

4. The method of claim 1, wherein determining initial model parameters comprises:
measuring an open-circuit voltage when the battery is fully charged (OCV_FC);
obtaining a slope (S) of the battery model in the linear region;
determining an intersection point of the linear region with the DOD=zero axis (OCV_FC_EFF) based on the slope; and
defining a union point between the parabolic region and the linear region of the battery model (DODX).

5. The method of claim 4, wherein measuring OCV_FC occurs after a settle time period elapses after charging the battery.

6. The method of claim 4, wherein S is obtained by performing a slow discharge of the battery with intermediate settle periods.

7. The method of claim 4, wherein the parabolic region occurs for DOD less than DODX and the linear region occurs for DOD greater than or equal to DODX.

8. The method of claim 4, wherein DODX may be defined as a value between 15% and 30% of DOD.

9. The method of claim 8, wherein the value of DODX is adjusted up or down based on a specific battery application or configuration.

10. A battery monitoring system comprising:
a battery sensor connectable to a battery; and
an energy management system configured to be coupled to the battery sensor and configured to calculate a state of charge (SOC) of the battery using a dynamic open circuit voltage (OCV) versus depth of discharge (DOD) battery model having a parabolic region and a linear region.

11. The battery monitoring system of claim 10, wherein the energy management system includes an estimation unit configured to estimate the SOC of the battery based on the battery model and a controller configured to send control signals to vehicle loads or an alternator based on the SOC of the battery.

12. The battery monitoring system of claim 10, wherein the energy management system is configured to:
determine initial model parameters for the OCV versus DOD battery model;
obtain model constants for the battery model from the model parameters;
receive a voltage measured from poles of the battery; and
calculate the SOC based on the voltage and the model constants of the battery model.

13. The battery monitoring system of claim 12, wherein the energy management system is further configured to:
update the initial model parameters to obtain updated model parameters for the battery model; and
obtain updated model constants from the updated model parameters.

14. The battery monitoring system of claim 12, wherein the SOC is based on the DOD of the battery and the DOD is estimated from the battery model based on the measured voltage of the vehicle battery.

15. The battery monitoring system of claim 12, wherein the initial model parameters comprise:
an open-circuit voltage when the battery is fully charged (OCV_FC);
a slope (S) of the battery model in the linear region;
an intersection point of the linear region with the DOD=zero axis (OCV_FC_EFF) based on the slope; and
a union point between the parabolic region and the linear region of the battery model (DODX).

16. The battery monitoring system of claim 15, wherein the parabolic region occurs for DOD less than DODX and the linear region occurs for DOD greater than or equal to DODX.

17. An energy management system for a vehicle battery comprising:
an estimation unit configured to:
determine initial model parameters for an open circuit voltage (OCV) versus depth of discharge (DOD) battery model;
obtain model constants for the battery model from the model parameters;
receive a voltage measured from poles of the vehicle battery; and
calculate a state of charge (SOC) of the vehicle battery based on the voltage and the model constants of the battery model; and
a controller configured to send control signals to vehicle loads or an alternator based on the SOC of the battery.

18. The energy management system of claim 17, wherein the DOD of the battery is estimated from the battery model based on the measured voltage of the vehicle battery and the SOC is calculated based on the DOD.

19. The energy management system of claim 17, wherein the battery model includes a parabolic region and a linear region.

20. The energy management system of claim 19, wherein the initial model parameters comprise:
an open-circuit voltage when the battery is fully charged (OCV_FC);
a slope (S) of the battery model in the linear region;
an intersection point of the linear region with the DOD=zero axis (OCV_FC_EFF) based on the slope; and
a union point between the parabolic region and the linear region of the battery model (DODX).
